(19) United States
(12) Patent Application Publication
(10) Pub. No.: US 2026/0075832 A1
(43) Pub. Date: Mar. 12, 2026

(54) ELECTROCHEMICAL MEMORY DEVICE AND DRIVING METHOD THEREOF

(71) Applicant: Samsung Electronics Co., Ltd., Suwon-si (KR)

(72) Inventors: Jeeeun YANG, Suwon-si (KR); Sangwook KIM, Suwon-si (KR); Garam PARK, Suwon-si (KR); Minhyun LEE, Suwon-si (KR)

(73) Assignee: Samsung Electronics Co., Ltd., Suwon-si (KR)

(21) Appl. No.: 19/088,466

(22) Filed: Mar. 24, 2025

(30) Foreign Application Priority Data
Sep. 10, 2024 (KR) 10-2024-0123124

(51) Int. Cl. H10B 51/20; G11C 11/22; H10B 51/10; H10D 64/68

(52) U.S. Cl. CPC H10B 51/20; G11C 11/2275; H10B 51/10; H10D 64/689

(57) ABSTRACT

An electrochemical memory device may include a gate electrode, a channel layer including a semiconductor oxide, a ferroelectric layer between the gate electrode and the channel layer, and a reservoir layer between the channel layer and the ferroelectric layer.

### CROSS-REFERENCE TO RELATED APPLICATIONS

This application claims the benefit of Korean Patent Application No. 10-2024-0123124, filed on Sep. 10, 2024, in the Korean Intellectual Property Office, the disclosure of which is incorporated herein by reference in its entirety.

### BACKGROUND

### 1. Field

Example embodiments relate to an electrochemical memory device and/or a method of operating the electrochemical memory device.

### 2. Description of the Related Art

Electrochemical random-access memory (ECRAM) devices are known to have a structure that includes a conductive channel layer, an insulating electrolyte layer, an ion reservoir layer, and a gate electrode. The ECRAM devices operate as memory devices in which when a voltage is applied to the gate electrode, ions moves into and out of a conductive channel layer, and according thereto, the electrical conductivity of the conductive channel layer changes.

Since the ECRAM devices operate by moving ions, switching speed may be slow and their ion retention characteristics may be unfavorable.

### SUMMARY

An aspect provides an electrochemical memory device by which the ion retention characteristics and the operating speed is improved, and/or a method of operating the electrochemical memory device.

However, aspects example embodiments of the present disclosure are not limited to those described above, and other aspects may be inferred from the following example embodiments.

According to an example embodiment, an electrochemical memory device may include a gate electrode; a channel layer comprising a semiconductor oxide; a ferroelectric layer between the gate electrode and the channel layer; and a reservoir layer between the channel layer and the ferroelectric layer.

According an example embodiment, an electrochemical memory device may include a substrate; and a stacked structure on the substrate and extending in a direction perpendicular to a plane of the substrate. The stacked structure may include a source electrode, a drain electrode, a gate electrode between the source electrode and the drain electrode, a channel layer surrounding at least a portion of the gate electrode, a ferroelectric layer between the gate electrode and the channel layer, and a reservoir layer between the channel layer and the ferroelectric layer. The ferroelectric layer may surround at least a portion of the gate electrode; and the reservoir layer may surround at least a portion of the ferroelectric layer.

According to an example embodiment, a method of operating an electrochemical memory device may include applying a voltage to a gate electrode of the electrochemical memory device. The electrochemical memory device may include the gate electrode, a channel layer comprising a semiconductor oxide, a ferroelectric layer between the gate electrode and the channel layer, and a reservoir layer between the channel layer and the ferroelectric layer. When the voltage is applied to gate electrode, the ferroelectric layer may be polarized into a first charge and a second charge, an oxygen vacancy of the channel layer and an oxygen vacancy of the reservoir layer may increase or decrease independently, and an electrical conductivity of the channel layer may change compared to the electric conductivity of the channel layer when the voltage is not applied to the gate electrode.

Additional aspects of example embodiments will be set forth in part in the description which follows and, in part, will be apparent from the description, or may be learned by practice of the disclosure.

According to example embodiments, it is possible to provide an electrochemical memory device by which the ion retention characteristics and/or the operation speed is improved, and/or a method of operating the electrochemical memory device.

Effects of the present disclosure are not limited to those described above, and other effects may be made apparent to those skilled in the art from the following description.

### BRIEF DESCRIPTION OF THE FIGURES

These and/or other aspects, features, and advantages of inventive concepts will become apparent and more readily appreciated from the following description of example embodiments, taken in conjunction with the accompanying drawings of which:

FIG. 1 to FIG. 6 are each a cross-sectional view schematically illustrating at least a portion of an electrochemical memory device according to an example embodiment;

FIG. 7 and FIG. 8 are schematic cross-sectional views of an electrochemical memory device illustrated to explain a method of operating the electrochemical memory device according to an example embodiment;

FIG. 9 is a perspective view schematically illustrating at least a portion of an electrochemical memory device according to an example embodiment;

FIG. 10 is a cross-sectional view along line A-A′ of FIG. 9;

FIG. 11 is a plan view schematically illustrating at least a portion of an electrochemical memory device according to an example embodiment; and

FIG. 12 is a cross-sectional view along line B-B′ of FIG. 11.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with technical ideas of the present disclosure based on the principle that the inventor may appropriately define terms in order to explain inventive concepts in the best way. The example embodiments described in this specification and the configurations shown in the drawings are examples only and do not necessarily represent the entire technical ideas of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different embodiments may be described using the same reference numerals or symbols. In other words, even if a component or an element having the same reference numeral is shown in multiple drawings, the multiple drawings may not all represent one example embodiment.

In the present disclosure, when an element is described as being “directly on,” “adjacent to” or “in contact with” another element, the element may be understood as being in direct contact with or connected to the other element, and it may be understood that there is no other element between the two.

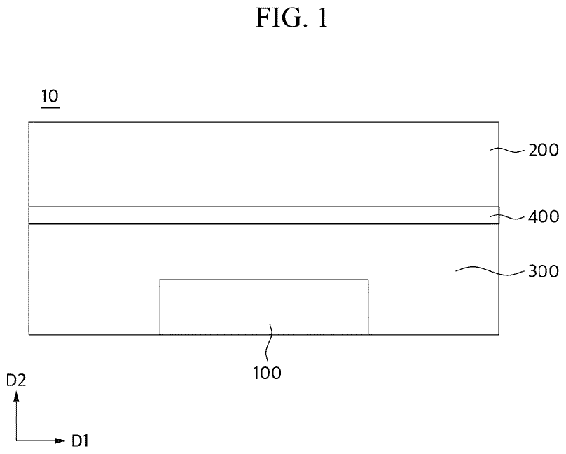

Further, in the present disclosure, when an element is described as being “on top of” another element, it may be understood as existing above the vertical direction, for example, as being above the +D2 direction in the drawing (FIG. 1), and the two elements may be in direct contact or connected, but it may also be understood that another element exists between the two. The same is applied even when an element is described as being “above” another element in the present disclosure.

Further, in the present disclosure, when an element is described as being “underneath” another element, it may be understood as existing below based on the vertical direction, for example, being further below based on the −D2 direction in the drawing (FIG. 1), and the two elements may be in direct contact or connected, but it may also be understood that another element exists between the two. The same is applied even when an element is described as being “beneath” another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

The drawings illustrated in the present disclosure are according to mere example embodiments, and the ratio of the width, the length and the height (or the thickness) of each element is for detailed descriptions for the example embodiments, and thus the ratio may differ from reality. Further, each component illustrated in the drawings may be exaggerated to illustrate the present disclosure in detail. Further, in the coordinate system illustrated in the drawings, each axis may be perpendicular to each other, and the direction the arrow points may be the + direction, and the direction opposite to the direction indicated by the arrow (rotated by 180 degrees) may be the − direction.

FIG. 1 to FIG. 6 are each a cross-sectional view schematically illustrating at least a portion of an electrochemical memory device 10 according to an example embodiment.

In the present disclosure, the first direction D1 may indicate a direction parallel to the plane of a substrate 20. Further, in the present disclosure, the second direction D2 may indicate a direction that is perpendicular to the plane of the substrate 20 and perpendicular to the first direction D1. Further, in the present disclosure, the third direction D3 may indicate a direction parallel to the plane of the substrate 20 and perpendicular to the first direction D1.

In an example embodiment, the electrochemical memory device 10 may include a gate electrode 100. In an example embodiment, the gate electrode 100 may be electrically connected to a word line. In an example embodiment, the gate electrode 100 may include a metal material having excellent electrical conductivity, a metal nitride, or silicon doped with impurities. In an example embodiment, the gate electrode 100 may include at least one selected from the group consisting of a metal material consisting of gold (Au), silver (Ag), aluminum (Al), titanium (Ti), indium (In), cadmium (Cd), copper (Cu), zinc (Zn), tantalum (Ta), molybdenum (Mo), and tungsten (W). However, the gate electrode 100 is not limited thereto. In an example embodiment, the gate electrode 100 may include a metal nitride (for example, TiN, etc.) including the above-described metal material. However, the gate electrode 100 is not limited thereto.

In an example embodiment, the electrochemical memory device 10 may function as a memory device in such a way that when a voltage is applied to the gate electrode 100, the oxygen vacancy of at least some layers increases or decreases due to the movement of oxygen ions. In the present disclosure, the increase and decrease of oxygen vacancy may be caused by the movement of oxygen ions, and the direction of movement of oxygen vacancy may be opposite to the direction of movement of oxygen ions. In other words, the increase in oxygen vacancy could indicate that oxygen ions are moving to another layer, and the decrease in oxygen vacancy could indicate that oxygen ions are moving from another layer.

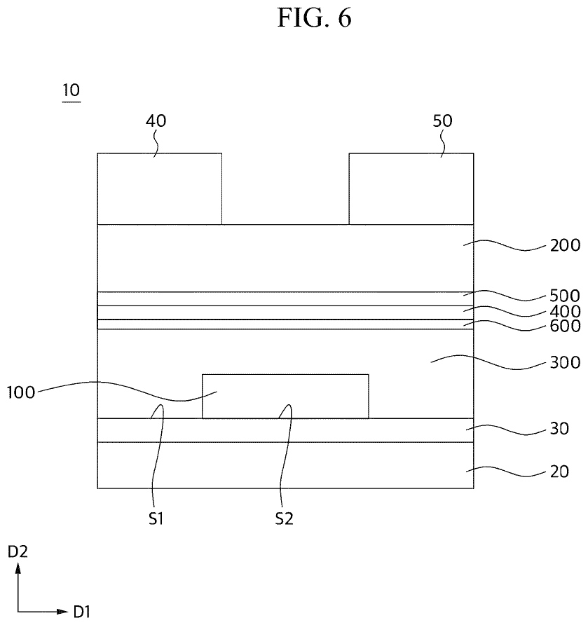

In an example embodiment, the electrochemical memory device 10 may include a channel layer 200. In an example embodiment, the channel layer 200 may be connected to a source electrode 40 and a drain electrode 50 (see FIG. 6).

In an example embodiment, the channel layer 200 may include a semiconductor oxide. In an example embodiment, the channel layer 200 may be an oxide including at least one selected from the group consisting of tantalum (Ta), hafnium (Hf), aluminum (Al), zinc (Zn), tungsten (W), vanadium (V), titanium (Ti), niobium (Nb), silicon (Si), germanium (Ge), arsenic (As), tellurium (Te), antimony (Sb), gallium (Ga), indium (In), zirconium (Zr), tin (Sn), and nickel (Ni). In an example embodiment, the channel layer 200 may be indium gallium zinc oxide (IGZO). However, the channel layer 200 is not limited thereto, and may include at least one selected from the group consisting of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum, zinc tin oxide (AlZnSnO), gallium zinc tin oxide (GaZnSnO), zirconium zinc tin oxide (ZrZnSnO) and indium gallium silicon oxide (InGaSiO).

In an example embodiment, the channel layer 200 may increase or decrease oxygen vacancies depending on the voltage applied to the gate electrode 100. In an example embodiment, compared to before voltage is applied to the gate electrode 100, the electrical conductivity of the channel layer 200 may vary depending on the voltage applied to the gate electrode 100. In an example embodiment, the electrochemical memory device 10 may function as a memory device through the electrical conductivity of the channel layer 200 that varies. The detailed operating method of the electrochemical memory device 10 will be described later. In an example embodiment, the electrochemical memory device 10 may include a ferroelectric layer 300. In an example embodiment, the ferroelectric layer 300 may have spontaneous polarization characteristics due to an applied electric field, and may have remnant polarization even in the absence of an electric field after having the spontaneous polarization characteristics. In an example embodiment, the ferroelectric layer 300 may be placed between the gate electrode 100 and the channel layer 200.

In an example embodiment, the ferroelectric layer 300 is not particularly limited as long as it has ferroelectric properties, but it may include a compound having ferroelectric properties and including one or more elements selected from the group consisting of hafnium (Hf) and zirconium (Zr). In an example embodiment, the ferroelectric layer 300 may include hafnium oxide (HfO), a compound including hafnium (Hf), zirconium oxide (ZrO), a compound including zirconium (Zr), or Hf—Zr oxide hafnium-zirconium oxide (HZO), a compound including hafnium (Hf) and zirconium (Zr). Further, the ferroelectric layer 300 is not limited thereto, and may include at least one selected from the group consisting of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF0·5Zr0·5O₂, PbZrₓTi₁₋ₓO₃ (0<x<1), Ba(Sr, Ti)O₃, Bi₄-xLaₓTi₃O₁₂ (0<x<1), SrBi₂Ta₂O₉, Pb₅Ge₅O₁₁, SrBi₂Nb₂O₉ and YMnO₃. In an example embodiment, the ferroelectric layer 300 may include a compound doped with impurity, and the impurity may include, for example, one or more selected from the group consisting of carbon (C), silicon (Si), magnesium (Mg), aluminum (Al), yttrium (Y), nitrogen (N), germanium (Ge), and tin (Sn), gadolinium (Gd), lanthanum (La), scandium (Sc), and strontium (Sr).

In an example embodiment, the ferroelectric layer 300 may have spontaneous polarization characteristics when voltage is applied to the gate electrode 100.

In an example embodiment, the electrochemical memory device 10 may include a reservoir layer 400. In an example embodiment, the reservoir layer 400 may be placed between the channel layer 200 and the ferroelectric layer 300. In an example embodiment, the reservoir layer 400 may be an insulating layer. In the present disclosure, the insulating layer may include an electrical conductivity of less than 10⁻⁶ S/m. The electrical conductivity is not specifically limited, but the electrical conductivity may be measured, for example, by ASTM E 1004.

In an example embodiment, the reservoir layer 400 may be a material with excellent ion storage properties. In an example embodiment, in the reservoir layer 400, the oxygen vacancy may increase or decrease depending on the voltage applied to the gate electrode 100. In an example embodiment, when voltage is applied to the gate electrode 100, the oxygen vacancy of the reservoir layer 400 may increase or decrease in the opposite direction to that of the channel layer 200. In an example embodiment, when voltage is applied to the gate electrode 100, if the oxygen vacancy of the channel layer 200 increases, the oxygen vacancy of the reservoir layer 400 may decrease, and if the oxygen vacancy of the channel layer 200 decreases, the oxygen vacancy of the reservoir layer 400 may increase. In an example embodiment, when voltage is applied to the gate electrode 100, the oxygen vacancy of the channel layer 200 and the oxygen vacancy the reservoir layer 400 may increase or decrease respectively due to the movement of oxygen ions. According thereto, the electrical conductivity of the channel layer 200 may be changed.

In an example embodiment, the reservoir layer 400 may include a first oxide having a metal element-oxygen bond. In an example embodiment, the first oxide may be an oxide including at least one metal element selected from the group consisting of metallic elements consisting of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn) and nickel (Ni). However, the first oxide is not limited thereto. In an example embodiment, the first oxide may include at least one of a single metal oxide in which one metal element selected from the group of metal elements described above is combined with oxygen and a composite metal oxide in which two or more metal elements selected from the group of metal elements described above are combined with oxygen. In an example embodiment, the first oxide may contain hafnium oxide.

In an example embodiment, the first oxide may be in an unmatched state, where the matching combination ratio of the metal element and oxygen is not satisfactory. In the present disclosure, the unmatched state may indicate a state in which an oxide does not satisfy the octet rule or the 18-electron rule. For example, the first oxide may satisfy MeO₂₋ₓ(0<x<2) when the matching combination ratio of metal (Me) and oxygen (O) is Me:O=1:2. More specifically, the first oxide contains hafnium oxide, and the chemical formula of hafnium oxide may satisfy HfO₂₋ₓ(0<x<2). In an example embodiment, since the reservoir layer 400 includes the first oxide of the unmatched state, the electrochemical memory device 10 may be function as a memory device.

In an example embodiment, the oxygen dissociation energy of the reservoir layer 400 may be lower than the oxygen dissociation energy of the channel layer 200. According thereto, the energy required for reservoir layer 400 to receive oxygen vacancy from channel layer 200 or to transfer oxygen vacancy to channel layer 200 can be reduced. In an example embodiment, the oxygen dissociation energy of the channel layer 200 may be 550 kJ/mol or less. The oxygen dissociation energy may be determined by the type of semiconductor oxide included in the channel layer 200. In the present disclosure, oxygen dissociation energy may be defined as the standard bond enthalpy between a specific element and oxygen, and the standard bond enthalpy may be defined as the energy required to separate a specific element from oxygen by breaking one mole of covalent bonds between the element and oxygen in the gaseous state, according to the international union of pure and applied chemistry (IUPAC) definition.

In an example embodiment, the electrochemical memory device 10 may include an electrolyte layer 500. In an example embodiment, the electrolyte layer 500 may be placed between the channel layer 200 and the reservoir layer 400. In an example embodiment, the electrolyte layer 500 may be an insulating layer.

In an example embodiment, the electrolyte layer 500 may include a material having excellent ion conductivity. In an example embodiment, the electrolyte layer 500 may make the electrochemical memory device 10 improve functioning as a memory device by facilitating the movement of oxygen ions between the channel layer 200 and the reservoir layer 400.

In an example embodiment, the electrolyte layer 500 may include a second oxide having a metal element-oxygen bond. In an example embodiment, the second oxide may be an oxide including at least one selected from the group of metal elements consisting of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni). However, the electrolyte layer 500 is not limited thereto. In an example embodiment, the second oxide may include at least one of a single metal oxide in which one metal element selected from the group of metal elements described above is combined with oxygen and a composite metal oxide in which two or more metal elements selected from the group of metal elements described above are combined with oxygen. In an example embodiment, the second oxide may include hafnium oxide and/or zirconium oxide.

In an example embodiment, the second oxide may be an in unmatched state in which the matching combination ratio of the metal element and oxygen is not satisfied. In an example embodiment, the second oxide may satisfy MeO₂₋ₓ(0<x<2) when the matching combination ratio of metal (Me) and oxygen (O) is Me:O=1:2. More specifically, the second oxide may include hafnium oxide, and the chemical formula of hafnium oxide may satisfy HfO₂₋ₓ(0<x<2). In an example embodiment, since the electrolyte layer 500 includes the second oxide in an unmatched state, the electrochemical memory device 10 may improve functioning as a memory device.

In an example embodiment, the oxygen dissociation energy of the electrolyte layer 500 is not limited, but may be lower than the oxygen dissociation energy of the channel layer 200. Through this, the electrochemical memory device 10 may improve functioning as a memory device.

In an example embodiment, the electrolyte layer 500 may include a material having an oxygen dissociation energy lower than the oxygen dissociation energy of the reservoir layer 400 among the example embodiments of the second oxide described above. The reservoir layer 400 may include a material having an oxygen dissociation energy higher than the oxygen dissociation energy of the electrolyte layer 500 among the example embodiments of the first oxide described above. The ferroelectric layer 300 may include a material having the oxygen dissociation energy higher than the oxygen dissociation energy of the reservoir layer 400 among the materials having the above-described ferroelectric properties.

In another example embodiment, the oxygen dissociation energy of the electrolyte layer 500 may be equal to or higher than the oxygen dissociation energy of the channel layer 200.

In an example embodiment, the electrochemical memory device 10 may include a barrier layer 600. In an example embodiment, the barrier layer 600 may be placed between the ferroelectric layer 300 and the reservoir layer 400. In an example embodiment, the barrier layer 600 may be an insulating layer.

In an example embodiment, the barrier layer 600 may include a material having low ionic conductivity. In an example embodiment, the barrier layer 600 limits and/or prevents oxygen ions from moving from the reservoir layer 400 to the ferroelectric layer 300, thereby limiting and/or minimizing the increase or decrease in oxygen vacancy in the ferroelectric layer 300. In an example embodiment, the barrier layer 600 may include a third oxide having a metal element-oxygen bond. In an example embodiment, the third oxide may be an oxide including at least one selected from the group of metal elements consisting of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni). However, the third oxide is not limited thereto. In an example embodiment, the second oxide may include at least one of a single metal oxide in which one metal element selected from the group of metal elements described above is combined with oxygen and a composite metal oxide in which two or more metal elements selected from the group of metal elements described above are combined with oxygen. In an example embodiment, the third oxide may include at least one selected from the group including aluminum oxide and tin oxide.

In an example embodiment, the oxygen dissociation energy of the barrier layer 600 may be higher than the oxygen dissociation energy of the ferroelectric layer 300. Through this, the electrochemical memory device 10 may improve functioning as a memory device. In an example embodiment, the barrier layer 600 may include a material having an oxygen dissociation energy higher than the oxygen dissociation energy of the ferroelectric layer 300.

In an example embodiment, as described above, the reservoir layer 400 may contain the first oxide, the electrolyte layer 500 may contain the second oxide, and the barrier layer 600 may contain the third oxide.

In an example embodiment, each of the first oxide, the second oxide and the third oxide may be an oxide independently including at least one selected from the group of metal elements consisting of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn), and nickel (Ni). Further, the first oxide, the second oxide and the third oxide may be selected as appropriate materials to satisfy the ionic conductivity, ion storage capacity, or oxygen dissociation energy relationship between adjacent layers of the reservoir layer 400, the electrolyte layer 500, and the barrier layer 600, respectively.

Referring to FIG. 1, in an example embodiment, the electrochemical memory device 10 may include the gate electrode 100, the channel layer 200, the ferroelectric layer 300, and the reservoir layer 400. In an example embodiment, in the electrochemical memory device 10, the ferroelectric layer 300 may be in contact with the gate electrode 100, the reservoir layer 400 may be in contact with the ferroelectric layer 300, and the channel layer 200 may be in contact with the upper part of the reservoir layer 400.

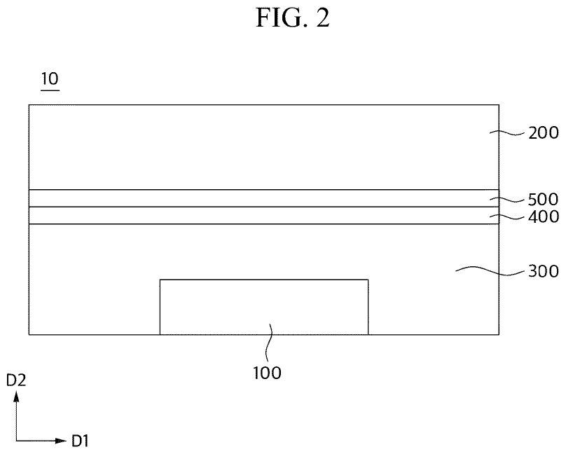

Referring to FIG. 2, in an example embodiment, the electrochemical memory device 10 may include the gate electrode 100, the channel layer 200, the ferroelectric layer 300, the reservoir layer 400, and the electrolyte layer 500. In an example embodiment, in the electrochemical memory device 10, the ferroelectric layer 300 may be in contact with the upper portion of the gate electrode 100, the reservoir layer 400 may be in contact with the upper portion of the ferroelectric layer 300, the electrolyte layer 500 may be in contact with the reservoir layer 400, and the channel layer 200 may be in contact with the electrolyte layer 500.

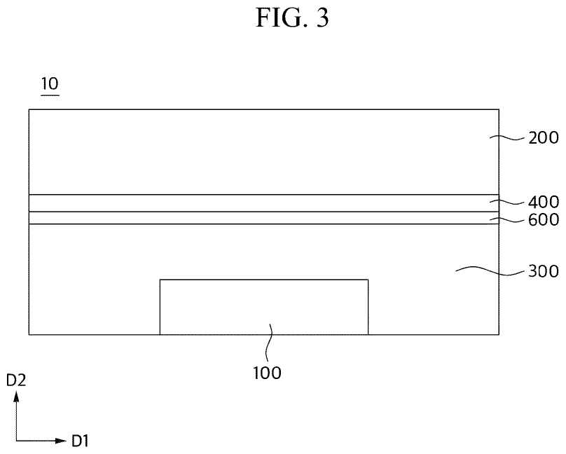

Referring to FIG. 3, in an example embodiment, the electrochemical memory device 10 may include the gate electrode 100, the channel layer 200, the ferroelectric layer 300, the reservoir layer 400, and the barrier layer 600. In an example embodiment, in the electrochemical memory device 10, the memory device 10 may have the ferroelectric layer 300 in contact with the upper portion of the gate electrode 100, and the barrier layer 600 in contact with the upper portion of the ferroelectric layer 300, the reservoir layer 400 may be in contact with the upper portion of the barrier layer 600, and the channel layer 200 may be in contact with the upper portion of the reservoir layer 400.

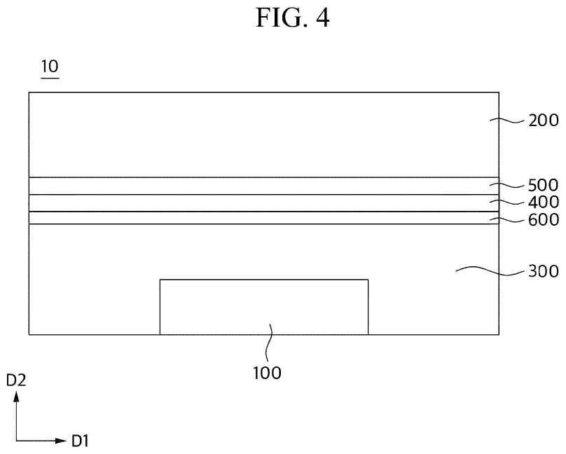

Referring to FIG. 4, in an example embodiment, the electrochemical memory device 10 may include the gate electrode 100, the channel layer 200, the ferroelectric layer 300, the reservoir layer 400, the electrolyte layer 500, and the barrier layer 600. In an example embodiment, in the electrochemical memory device 10, the ferroelectric layer 300 may be in contact with the upper portion of the gate electrode 100, and the barrier layer 600 may be in contact with the upper portion of the ferroelectric layer 300, the reservoir layer 400 may be in contact with the barrier layer 600, the electrolyte layer 500 may be in contact with the reservoir layer 400, and the channel layer 200 may be in contact with the upper part of the electrolyte layer 500.

In an example embodiment, the electrochemical memory device 10 may include the substrate 20. In an example embodiment, the substrate 20 may be, but is not particularly limited to, a silicon semiconductor substrate, a plastic substrate, a glass substrate, a compound semiconductor substrate, a ceramic substrate, or a silicon on insulator (SOI) substrate. In an example embodiment, the substrate 20 may include, although not illustrated separately, an impurity region due to doping, a periphery circuit for selecting and controlling an electronic device such as a transistor or a memory cell. In an example embodiment, the gate electrode 100 may be positioned between the channel layer 200 and the substrate 20.

In an example embodiment, the electrochemical memory device 10 may include an oxide layer 30. In an example embodiment, the oxide layer 30 may be disposed on the substrate 20. In an example embodiment, the oxide layer 30 may be in contact with the substrate 20.

In an example embodiment, the oxide layer 30 may surround at least a portion of the gate electrode 100 and the ferroelectric layer 300. In an example embodiment, the oxide layer 30 may be in contact with the gate electrode 100 and the ferroelectric layer 300. In an example embodiment, a first plane S1 in which the gate electrode 100 and the oxide layer 30 are in contact and a second plane S2 in which the ferroelectric layer 300 and the oxide layer 30 are in contact may be arranged on the same plane. In an example embodiment, the oxide layer 30 may include at least one selected from the group consisting of silicon oxide and silicon oxynitride, but the oxide layer 30 is not limited thereto.

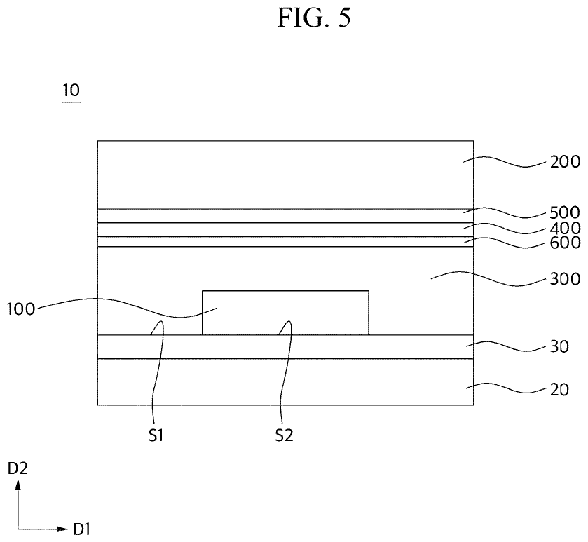

Referring to FIG. 5, the electrochemical memory device 10 may include the substrate 20, the oxide layer 30, the gate electrode 100, the channel layer 200, the ferroelectric layer 300, the reservoir layer 400, the electrolyte layer 500, and the barrier layer 600. In an example embodiment, in the electrochemical memory device 10, the oxide layer 30 may be in contact with the substrate 20, the gate electrode 100 and the ferroelectric layer 300 may be in contact with the oxide layer 30, the ferroelectric layer 300 may be in contact with the upper portion of the gate electrode 100, the barrier layer 600 may be in contact with the upper portion of the ferroelectric layer 300, the reservoir layer 400 may be in contact with the barrier layer 600, the electrolyte layer 500 may be in contact with the reservoir layer 400, and the channel layer 200 may be in contact with the upper part of the electrolyte layer 500. In an example embodiment, the first plane S1 where the gate electrode 100 and the oxide layer 30 are in contact and the second plane S2 where the ferroelectric layer 300 and the oxide layer 30 are in contact may be arranged on the same plane, and the oxide layer 30 may be in contact with at least a portion of the gate electrode 100, the channel layer 200, the ferroelectric layer 300, the reservoir layer 400, the electrolyte layer 500, and the barrier layer 600.

Referring to FIG. 6, in an example embodiment, the electrochemical memory device 10 may include the source electrode 40 and the drain electrode 50 connected to the channel layer 200. In an example embodiment, the source electrode 40 and the drain electrode 50 may be in contact with at least a portion of the oxide layer 30. In an example embodiment, the oxide layer 30 may be in non-contact with the source electrode 40 and the drain electrode 50.

In an example embodiment, each of the source electrode 40 and the drain electrode 50 may independently include a conductive material. In an example embodiment, the conductive material may include, for example, one or more selected from the group consisting of doped polysilicon, a metal, a conductive metal nitride, a conductive metal silicide, and a conductive metal oxide. In an example embodiment, the metal may include at least one selected from the group consisting of aluminum (Al), copper (Cu), titanium (Ti), tantalum (Ta), rubidium (Ru), tungsten (W), molybdenum (Mo), platinum (Pt), nickel (Ni), and cobalt (Ti). In an example embodiment, the conductive metal nitride may include TiAl and/or TiAlN. In an example embodiment, the conductive metal silicide may include one or more selected from the group consisting of TiSi, TiSiN, TaSi, TaSiN, RuTiN, NiSi and CoSi. In an example embodiment, the conductive metal oxide may include IrOx and/or RuOx.

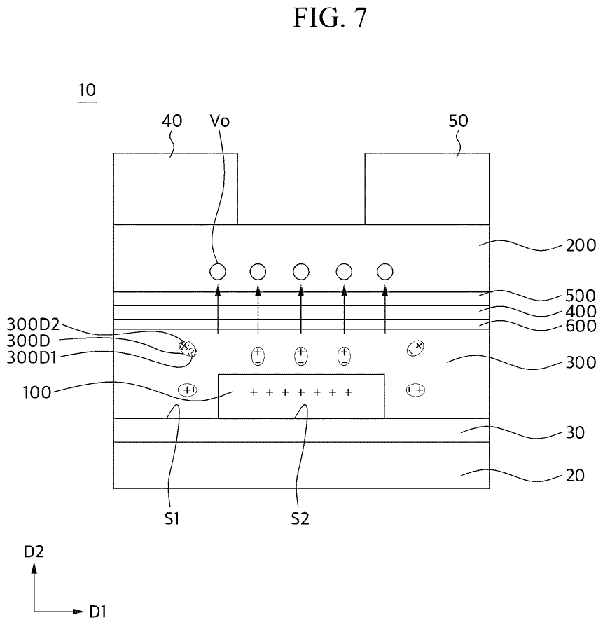

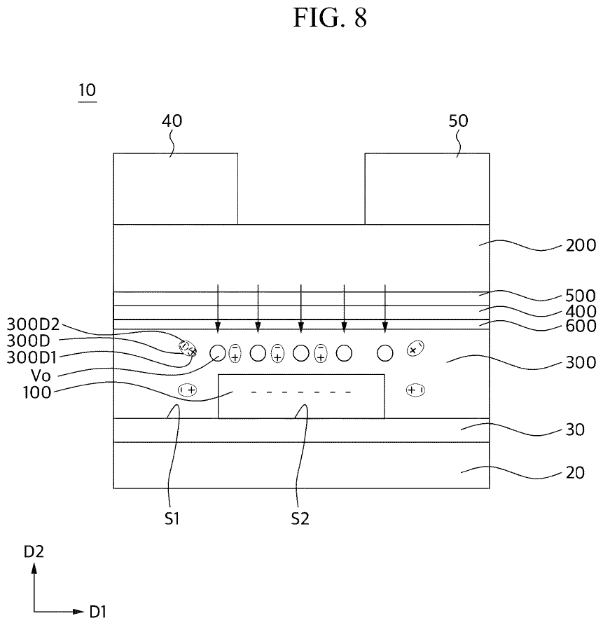

FIG. 7 and FIG. 8 are schematic cross-sectional views of the electrochemical memory device 10 illustrated to explain a method of operating the electrochemical memory device 10 according to an example embodiment.

In an example embodiment, when voltage is applied to the gate electrode 100, the oxygen vacancy (Vo) of the channel layer 200 and the oxygen vacancy (Vo) of the reservoir layer 400 may independently increase or decrease. At the same time, the ferroelectric layer 300 may have spontaneous polarization characteristics. In an example embodiment, the spontaneous polarization of the ferroelectric layer 300 may be further induced by increasing or decreasing the oxygen vacancy (Vo) of the channel layer 200 and the oxygen vacancy (Vo) of the reservoir layer 400.

In an example embodiment, when voltage is applied to the gate electrode 100, the oxygen vacancy (Vo) of the reservoir layer 400 may decrease and the oxygen vacancy (Vo) of the channel layer 200 may increase. Through this, the electrical conductivity of the channel layer 200 may be different from the electrical conductivity of the channel layer 200 before voltage is applied to the gate electrode 100.

In an example embodiment, the ferroelectric layer 300 may include a domain 300D. In an example embodiment, the ferroelectric layer 300 may include multiple domains 300D. In an example embodiment, when voltage is applied to the gate electrode 100, the domain 300D included in the ferroelectric layer 300 may be polarized by a first charge 300D1 and a second charge 300D2 having the opposite polarity to the first charge 300D1. In an example embodiment, the ferroelectric layer 300 may be polarized into the first charge 300D1 and the second charge 300D2 when a voltage is applied to the gate electrode 100. In an example embodiment, the first charge 300D1 may have a polarity opposite to the gate applied voltage. For example, when the first charge 300D1 is a positive charge, the second charge 300D2 may be a negative charge, and when the first charge 300D1 is a negative charge, the second charge 300D2 may be a positive charge.

In an example embodiment, when voltage is applied to the gate electrode 100, the electrolyte layer 500 may make the electrochemical memory device 10 improve functioning as a memory device by facilitating the movement of oxygen ions between the channel layer 200 and the reservoir layer 400.

In an example embodiment, when voltage is applied to the gate electrode 100, the barrier layer 600 may limit and/or minimize the increase or decrease in the oxygen vacancy (Vo) of the ferroelectric layer 300 by preventing oxygen ions from moving from the reservoir layer 400 to the ferroelectric layer 300.

In an example embodiment, when a positive voltage is applied to the gate electrode 100, the oxygen vacancy (Vo) may decrease in the reservoir layer 400 and the oxygen vacancy (Vo) may increase in the channel layer 200. At the same time, the first charge 300D1 of the ferroelectric layer 300 may be a negative charge, and the second charge 300D2 may be a positive charge.

In an example embodiment, when a negative voltage is applied to the gate electrode 100, the oxygen vacancy (Vo) may increase in the reservoir layer 400 and the oxygen vacancy (Vo) may decrease in the channel layer 200. At the same time, with regard to the ferroelectric layer 300, the first charge 300D1 may be a positive charge, and the second charge 300D2 may be a negative charge.

In an example embodiment, the method of operating the electrochemical memory device 10 may include that when voltage is applied to the gate electrode 100, the ferroelectric layer 300 is spontaneously polarized into the first charge 300D1 and the second charge 300D2. In an example embodiment, the method of operating the electrochemical memory device 10 may include that when voltage is applied to the gate electrode 100, as the ferroelectric layer 300 undergoes spontaneous polarization, the oxygen vacancy (Vo) of the channel layer 200 and the oxygen vacancy (Vo) of the reservoir layer 400 independently increases or decreases. Here, the electrical conductivity of the channel layer 200 may be different when compared to before voltage is applied to the gate electrode 100, and the method of operating the electrochemical memory device 10 may include writing (or programming) or erasing as the electrical conductivity of the channel layer 200 changes.

In an example embodiment, the method of operating the electrochemical memory device 10 may include writing for which, when a positive voltage is applied to the gate electrode 100, the oxygen vacancy (Vo) decreases in the reservoir layer 400 and the oxygen vacancy (Vo) increases in the channel layer 200, and the electrical conductivity of the channel layer 200 increases compared to before voltage is applied to the gate electrode 100. Here, the method of operating the electrochemical memory device 10 may include erasing for which, when the voltage applied to the gate electrode 100 changes from positive to negative voltage, the oxygen vacancy (Vo) increases in the reservoir layer 400, the oxygen vacancy (Vo) decreases in the channel layer 200 for recovery, and is restored, and the electrical conductivity of the channel layer 200 decreases compared to when a positive voltage is applied to the gate electrode 100. Further, the negative voltage applied to the gate electrode 100 may be sufficient to reverse the polarization beyond the coercive field voltage that clears the residual polarization state of the ferroelectric layer 300.

In an example embodiment, writing may be that the positive voltage is applied to the gate electrode 100, the first charge 300D1 is a negative charge and the second charge 300D2 is a positive charge, and the electrical conductivity of the channel layer 200 increases compared to when before voltage is applied to the gate electrode 100. In an example embodiment, if writing is applying positive voltage to the gate electrode 100, erasing may be applying negative voltage to the gate electrode 100, the first charge 300D1 is a positive charge and the second charge 300D2 is a negative charge, and the electrical conductivity of the channel layer 200 is reduced compared to when a positive voltage is applied to the gate electrode 100. Here, as described above, the negative voltage may be sufficient to reverse the polarization beyond the coercive field voltage that clears the residual polarization state of the ferroelectric layer 300.

In an example embodiment, the method of operating the electrochemical memory device 10 may include writing in which, when a negative voltage is applied to the gate electrode 100, the oxygen vacancy (Vo) increases in the reservoir layer 400 and the oxygen vacancy (Vo) decreases in the channel layer 200, and the electrical conductivity of the channel layer 200 decreases compared to when before voltage is applied to the gate electrode 100. Here, the method of operating the electrochemical memory device 10 may include erasing in which, when a voltage is applied to the gate electrode 100 from negative to positive, the oxygen vacancy (Vo) decreases in the reservoir layer 400 and the oxygen vacancy (Vo) increases in the channel layer 200 to be restored, and the electrical conductivity of the channel layer 200 increases when a negative voltage is applied to the gate electrode 100. Further, the positive voltage applied to the gate electrode 100 may be sufficient to reverse the polarization beyond the coercive field voltage that clears the residual polarization state of the ferroelectric layer 300.

In an example embodiment, writing may be that negative voltage is applied to the gate electrode 100, the first charge 300D1 is a positive charge and the second charge 300D2 is a negative charge, and the electrical conductivity of the channel layer 200 decreases compared to before voltage is applied to the gate electrode 100. In an example embodiment, if writing is applying negative voltage to the gate electrode 100, erasing may be applying positive voltage to the gate electrode 100, and for erasing, the first charge 300D1 is a negative charge and the second charge 300D2 is a positive charge and electrical conductivity of the channel layer 200 increases compared to when a negative voltage is applied to the gate electrode 100. Here, as described above, the positive voltage may be sufficient to reverse the polarization by exceeding the coercive field voltage that clears the residual polarization state of the ferroelectric layer 300.

In an example embodiment, the method of operating the electrochemical memory device 10 may include writing and/or erasing by changing a threshold voltage (Vth) when a voltage is applied to the gate electrode 100. In an example embodiment, the threshold voltage may vary with changes in the conductivity of the channel layer 200, and when a positive voltage is applied to the gate electrode 100, the threshold voltage may decrease.

In an example embodiment, the method of operating the electrochemical memory device 10 may include reading which is identifying the electrical conductivity of the channel layer 200 by applying voltage to the gate electrode 100. Here, with regard to the voltage applied to the gate electrode 100, it may be desirable to apply a voltage so low that no movement of oxygen ions occurs. Further, in an example embodiment, the electrical conductivity of the channel layer 200 may vary depending on the degree of increase or decrease in the oxygen vacancy (Vo) within the channel layer 200. In an example embodiment, the electrical conductivity of the channel layer 200 may be measured as resistance through a current-voltage curve, and reading may be performed through this.

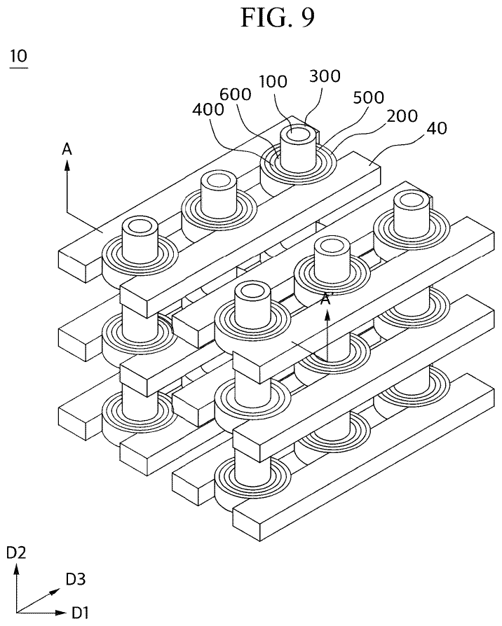

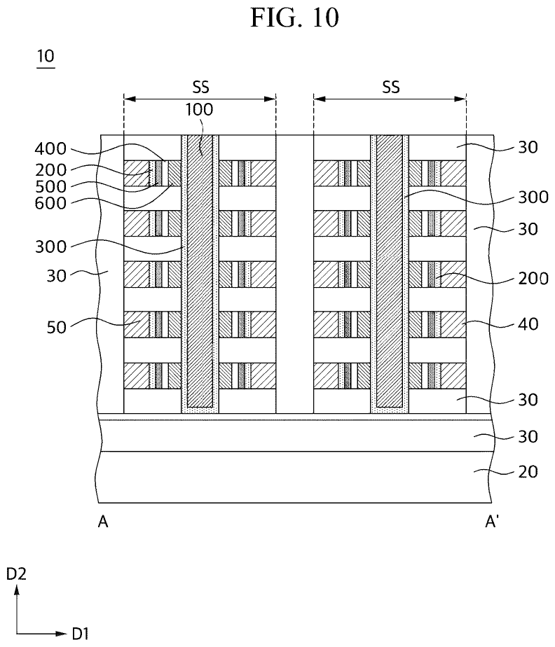

FIG. 9 is a perspective view schematically illustrating at least a portion of the electrochemical memory device 10 according to an example embodiment. FIG. 10 is a cross-sectional view along line A-A′ of FIG. 9. With regard to following descriptions, reference may be made to the above descriptions unless they are contradictory.

In an example embodiment, the electrochemical memory device 10 may include the substrate 20 and a stacked structure SS disposed on the substrate 20. In an example embodiment, the electrochemical memory device 10 may include the oxide layer 30 disposed on the substrate 20, and in an example embodiment, the stacked structure SS may be placed on the oxide layer 30. In an example embodiment, the electrochemical memory device 10 may include one or more stacked structures SS.

In an example embodiment, the stacked structure SS may extend in a direction perpendicular to the plane of the substrate 20 (in other words, the second direction D2). In an example embodiment, when there are a plurality of stacked structures SS, the plurality of stacked structures SS may be spaced apart from each other along the first direction D1 and the third direction D3, and spaced side by side with respect to the second direction D2.

In an example embodiment, the stacked structure SS may include the source electrodes 40 spaced apart from each other in the second direction D2, the drain electrodes 50 spaced apart from the source electrodes 40 along the first direction D1, and the gate electrode 100 placed between the source electrodes 40 and the drain electrodes 50. In an example embodiment, each of the source electrodes 40 and the drain electrodes 50 may extend along the third direction D3. In an example embodiment, the source electrodes 40 may be extended parallel to the drain electrodes 50 along the third direction D3. In an example embodiment, the gate electrode 100 may be placed between the source electrodes 40 and the drain electrodes 50. In an example embodiment, the gate electrode 100 may cross the source electrodes 40 and the drain electrodes 50. In an example embodiment, the gate electrode 100 may be extended to the second direction D2. In an example embodiment, the gate electrodes 100 may be spaced apart from each other in the third direction D3 between the source electrodes 40 and the drain electrodes 50.

In an example embodiment, the stacked structure SS may include the channel layers 200 surrounding at least a portion of the gate electrode 100. In an example embodiment, the channel layers 200 may surround the side of the corresponding the gate electrode 100, and be spaced apart from each other in the second direction D2. In an example embodiment, the channel layers 200 may be placed between the source electrodes 40 and the drain electrodes 50. In an example embodiment, each of the source electrodes 40 and the drain electrodes 50 may be connected to the channel layer 200.

In an example embodiment, the stacked structure SS may include the ferroelectric layer 300 positioned between the gate electrode 100 and the channel layer 200. In an example embodiment, the ferroelectric layer 300 may surround at least a portion of the gate electrode 100. In an example embodiment, the ferroelectric layer 300 may surround a side surface of a corresponding the gate electrode 100. In an example embodiment, the ferroelectric layer 300 may extend in the second direction D2. In an example embodiment, the ferroelectric layer 300 may extend in the second direction D2 along the gate electrode 100. In an example embodiment, the ferroelectric layer 300 may be arranged to surround part of the gate electrode 100 but be surrounded on the sides by the channel layer 200. In an example embodiment, the ferroelectric layer 300 may be spaced apart from the channel layer 200.

In an example embodiment, the stacked structure SS may include the reservoir layer 400 positioned between the channel layer 200 and the ferroelectric layer 300. In an example embodiment, the reservoir layer 400 may surround at least a portion of the ferroelectric layer 300. In an example embodiment, the reservoir layer 400 may surround a side surface of a corresponding ferroelectric layer 300. In an example embodiment, the reservoir layer 400 may be extended in the second direction D2. In an example embodiment, the reservoir layer 400 may extend in the second direction D2 along the ferroelectric layer 300. In an example embodiment, the reservoir layer 400 may be arranged to surround part of the ferroelectric layer 300 but be surrounded on the sides by the channel layer 200. In an example embodiment, the reservoir layer 400 may be arranged spaced apart from the channel layer 200.

In an example embodiment, the stacked structure SS may include the electrolyte layer 500 positioned between the channel layer 200 and the reservoir layer 400. In an example embodiment, the electrolyte layer 500 may surround at least a portion of the reservoir layer 400. In an example embodiment, the electrolyte layer 500 may surround the side of the corresponding reservoir layer 400. In an example embodiment, the electrolyte layer 500 may be extended in the second direction D2. In an example embodiment, the electrolyte layer 500 may extend in the second direction D2 along the reservoir layer 400. In an example embodiment, the electrolyte layer 500 may be arranged to surround part of the reservoir layer 400 but be surrounded on the sides by the channel layer 200. In an example embodiment, the electrolyte layer 500 may be arranged spaced apart from the channel layer 200.

In an example embodiment, the stacked structure SS may include the barrier layer 600 positioned between the ferroelectric layer 300 and the reservoir layer 400. In an example embodiment, the barrier layer 600 may surround at least a portion of the ferroelectric layer 300. In an example embodiment, the barrier layer 600 may surround the side of the corresponding ferroelectric layer 300. In an example embodiment, the barrier layer 600 may extend in the second direction D2. In an example embodiment, the barrier layer 600 may extend in the second direction D2 along the ferroelectric layer 300. In an example embodiment, the barrier layer 600 may be arranged to surround part of the ferroelectric layer 300 but be surrounded on the sides by the reservoir layer 400.

In an example embodiment, the oxide layer 30 may be in contact with at least a portion of the channel layer 200, the ferroelectric layer 300, the reservoir layer 400, the electrolyte layer 500, and the barrier layer 600. In an example embodiment, the oxide layer 30 may surround at least a portion of the source electrode 40 and the drain electrode 50.

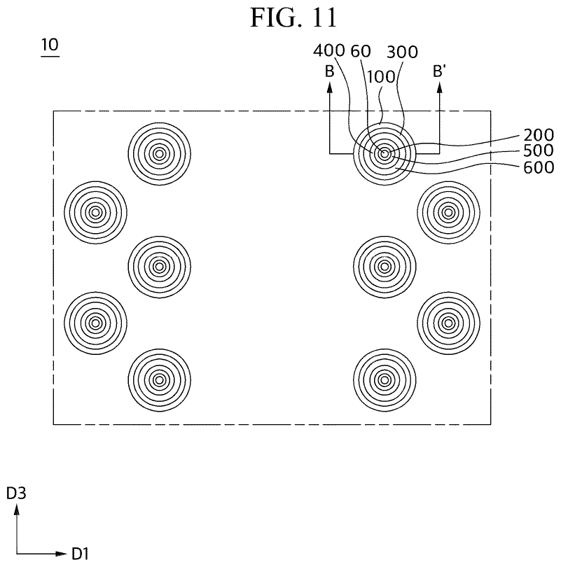

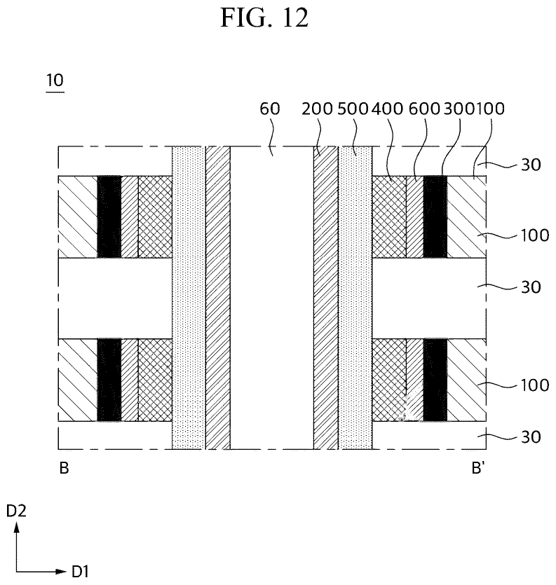

FIG. 11 is a plan view schematically illustrating at least a portion of an electrochemical memory device according to an example embodiment. FIG. 12 is a cross-sectional view along line B-B′ of FIG. 11. In relation to following description, reference may be made to the above descriptions unless they are contradictory. In an example embodiment, the electrochemical memory device 10 may have a structure similar to vertical type NAND flash. In relation to following description, reference may be made to the above descriptions unless they are contradictory.

In an example embodiment, the electrochemical memory device 10 may include the channel layer 200 extending along the second direction D2. In an example embodiment, the electrochemical memory device 10 may include a core pattern 60, and the channel layer 200 may at least partially wrap the core pattern 60. In an example embodiment, the core pattern 60 may include, for example, an insulating material, and specifically may include at least one selected from the group consisting of silicon oxide, silicon nitride and silicon oxynitride.

In an example embodiment, the electrochemical memory device 10 may include the electrolyte layer 500 surrounding at least a portion of the channel layer 200. In an example embodiment, the electrochemical memory device 10 may include the reservoir layer 400 surrounding at least a portion of the electrolyte layer 500. In an example embodiment, the electrochemical memory device 10 may include the barrier layer 600 surrounding at least a portion of the reservoir layer 400. In an example embodiment, the electrochemical memory device 10 may include the ferroelectric layer 300 surrounding at least a portion of the barrier layer 600. In an example embodiment, the electrochemical memory device 10 may include the gate electrode 100 surrounding at least a portion of the ferroelectric layer 300.

In an example embodiment, the electrolyte layer 500 may extend along the second direction D2. In an example embodiment, the channel layer 200, the electrolyte layer 500, the reservoir layer 400, the barrier layer 600, the ferroelectric layer 300, and the gate electrode 100 may be arranged along the first direction D1. In an example embodiment, the electrochemical memory device 10 may include a unit layer including the reservoir layer 400, the barrier layer 600, the ferroelectric layer 300, and the gate electrode 100. There may be a plurality of unit layers, and the unit layers may be spaced apart from each other in the second direction D2. In an example embodiment, the electrochemical memory device 10 may include the oxide layer 30 disposed between unit layers.

While example embodiments of the present disclosure have been described with reference to the attached drawings, the present disclosure is not limited to the presented embodiments. The present disclosure can be manufactured in various other forms, and a person skilled in the art to which the present disclosure pertains will understand that the present disclosure can be implemented in other specific forms without changing its technical idea or essential features. Therefore, example embodiments described above should be understood in all respects as illustrative and not limiting.

What is claimed is:

1. An electrochemical memory device comprising:
a gate electrode;
a channel layer comprising a semiconductor oxide;
a ferroelectric layer between the gate electrode and the channel layer; and
a reservoir layer between the channel layer and the ferroelectric layer.

2. The electrochemical memory device of claim 1,
wherein, when a voltage is applied to the gate electrode,
an oxygen vacancy of the channel layer and an oxygen vacancy of the reservoir layer each independently increase or decrease, and
the ferroelectric layer is polarized into a first charge and a second charge, wherein a polarity of the second charge is opposite a polarity of the first charge.

3. The electrochemical memory device of claim 2, wherein,
when a positive voltage is applied to the gate electrode, the oxygen vacancy of the reservoir layer decreases, the oxygen vacancy of the channel layer increases, the first charge is a negative charge, and the second charge is a positive charge, and
when a negative voltage is applied to the gate electrode, the oxygen vacancy of the reservoir layer increases and the oxygen vacancy of the channel layer decreases, and the first charge is a positive charge and the second charge is a negative charge.

4. The electrochemical memory device of claim 1, wherein
the reservoir layer comprises a first oxide, and
the first oxide comprises a metal element-oxygen bond.

5. The electrochemical memory device of claim 4, wherein the first oxide is in an unmatched state.

6. The electrochemical memory device of claim 4, wherein
the first oxide is an oxide includes at least one of tantalum (Ta), hafnium (Hf), aluminum (Al), zinc (Zn), tungsten (W), vanadium (V), titanium (Ti), niobium (Nb), germanium (Ge), arsenic (As), tellurium (Te), antimony (Sb), gallium (Ga), indium (In), zirconium (Zr), tin (Sn) and nickel (Ni).

7. The electrochemical memory device of claim 1, wherein an oxygen dissociation energy of the reservoir layer is lower than an oxygen dissociation energy of the channel layer.

8. The electrochemical memory device of claim 1, further comprising:
an electrolyte layer between the channel layer and the reservoir layer.

9. The electrochemical memory device of claim 8, wherein
the electrolyte layer comprises a second oxide, and
the second oxide comprises a metal element-oxygen bond.

10. The electrochemical memory device of claim 9, wherein the second oxide is in an unmatched state.

11. The electrochemical memory device of claim 1, further comprising:
a barrier layer between the ferroelectric layer and the reservoir layer.

12. The electrochemical memory device of claim 11, wherein an oxygen dissociation energy of the barrier layer is higher than an oxygen dissociation energy of the ferroelectric layer.

13. The electrochemical memory device of claim 1, further comprising:
a substrate; and
an oxide layer on the substrate,
wherein the gate electrode is between the channel layer and the substrate, and
wherein the oxide layer is in contact with at least a portion of the gate electrode and at least a portion of the ferroelectric layer.

14. An electrochemical memory device comprising:
a substrate; and
a stacked structure on the substrate and extending in a direction perpendicular to a plane of the substrate,
wherein the stacked structure comprises a source electrode, a drain electrode, a gate electrode between the source electrode and the drain electrode, a channel layer surrounding at least a portion of the gate electrode, a ferroelectric layer between the gate electrode and the channel layer, and a reservoir layer between the channel layer and the ferroelectric layer,
the ferroelectric layer surrounds at least a portion of the gate electrode; and
the reservoir layer surrounds at least a portion of the ferroelectric layer.

15. The electrochemical memory device of claim 14, wherein an oxygen dissociation energy of the reservoir layer is lower than an oxygen dissociation energy of the channel layer.

16. The electrochemical memory device of claim 15, wherein
the reservoir layer comprises a first oxide, and
the first oxide comprises a metal element-oxygen bond and is in an unmatched state.

17. A method of operating an electrochemical memory device, the method comprising:
applying a voltage to a gate electrode of the electrochemical memory device, wherein
the electrochemical memory device includes the gate electrode, a channel layer comprising a semiconductor oxide, a ferroelectric layer between the gate electrode and the channel layer, and a reservoir layer between the channel layer and the ferroelectric layer, and
when the voltage is applied to gate electrode, the ferroelectric layer is polarized into a first charge and a second charge, an oxygen vacancy of the channel layer and an oxygen vacancy of the reservoir layer increase or decrease independently, and an electrical conductivity of the channel layer changes compared to the electric conductivity of the channel layer when the voltage is not applied to the gate electrode.

18. The method of operating the electrochemical memory device of claim 17, wherein,
when the voltage is applied to the gate electrode, a threshold voltage (Vth) of the electrochemical memory device changes, and the electrochemical memory device performs writing or erasing.

19. The method of operating the electrochemical memory device of claim 17,
the applying the voltage to the gate electrode includes applying a positive voltage to the gate electrode during a writing operation or applying a negative voltage to the gate electrode during an erasing operation, wherein
in the writing operation, when the positive voltage is applied to the gate electrode, the first charge is a negative charge and the second charge is a positive charge, the oxygen vacancy of the reservoir layer decreases, the oxygen vacancy of the channel layer increases, and the electrical conductivity of the channel layer increases compared to when the applying the voltage to the gate electrode is not performed, and
in the erasing operation, when the negative voltage is applied to the gate electrode, the first charge is the positive charge and the second charge is the negative charge, the oxygen vacancy of the reservoir layer increases and the oxygen vacancy of the channel layer decreases, and the electrical conductivity of the channel layer decreases compared to when the applying the voltage to the gate electrode is not performed.

20. The method of operating the electrochemical memory device of claim 17,
the applying the voltage to the gate electrode includes applying a negative voltage to the gate electrode during a writing operation or applying a positive voltage to the gate electrode during an erasing operation, wherein in the writing operation, when the negative voltage is applied to the gate electrode, the first charge is a positive charge and the second charge is a negative charge, the oxygen vacancy of the reservoir layer increases and oxygen vacancy of the channel layer decreases, and an electrical conductivity of the channel layer decreases compared to when the applying the voltage to the gate electrode is not performed, and
in the erasing operation, when the positive voltage is applied to the gate electrode, the first charge is the negative charge and the second charge is the positive charge, the oxygen vacancy of the reservoir layer decreases and the oxygen vacancy of the channel layer increases, and the electrical conductivity of the channel layer increases compared to when the applying the voltage to the gate electrode is not performed.
